(19) United States
(12) Patent Application Publication
(10) Pub. No.: US 2013/0186379 A1
(43) Pub. Date: Jul. 25, 2013

(54) DISTRIBUTORLESS IGNITION KIT AND METHOD OF RETROFITTING THE DISTRIBUTORLESS IGNITION KIT TO AN ENGINE

(71) Applicants: Rickey Patterson, Montgomery, AL (US); Jeffrey Schrupp, Prattville, AL (US)

(72) Inventors: Rickey Patterson, Montgomery, AL (US); Jeffrey Schrupp, Prattville, AL (US)

(73) Assignee: Axiom Automotive Technologies, Inc., Cleveland, OH (US)

(21) Appl. No.: 13/798,862

(22) Filed: Mar. 13, 2013

Related U.S. Application Data
(63) Continuation of application No. 13/302,250, filed on Nov. 22, 2011, now abandoned.
Application No. 13/302,250 is a continuation of application No. 12/327,270, filed on Dec. 3, 2008, now abandoned.

(51) Int. Cl. F02D 45/00; H05K 13/00

(52) U.S. Cl. CPC F02D 45/00; H05K 13/00
USPC 123/612; 29/592.1

(57) ABSTRACT

A distributorless ignition kit is provided for retrofitting an existing engine having a distributor mounted in a distributor opening. The distributorless ignition kit comprises a coil pack having a series of spark plug wire terminals. A mounting bracket is provided for mounting the coil pack to the engine or adjacent the engine. A modified crankshaft pulley having a series of circumferentially spaced timing notches is provided in the kit. Further, there is provided a VR sensor that is adapted to be mounted adjacent the modified crankshaft pulley. A bracket is provided for mounting the VR sensor adjacent the modified crankshaft pulley. In order to direct firing signals from the VR sensor to the coil pack, there is provided a VR sensor cord that connects the VR sensor and the coil pack.

### BACKGROUND

In approximately 1987 the United States Postal Service started purchasing Grumman long life vehicles, commonly referred to as LLV Postal Vehicles. These are lightweight transport trucks that are typically used by letter carriers for curbside and residential delivery of mail.

Some of the Postal Service's LLV vehicles came equipped with an engine that used a distributor-type ignition system. Experience with the LLV vehicles indicates that these distributors tend to fail prematurely, and in some cases the distributors even fail soon after they are installed. There may be numerous causes for these failures but the malfunctioning of the Hall affect sensor and the pickup coil most likely is one of the more frequent causes of failure. These failures are not only expensive to repair, but such failures result in these vehicles being out of service and that, too, substantially contributes to the overall cost of distributor failures.

### SUMMARY

The present invention relates to a distributorless ignition kit configured to be retrofitted to an engine.

In one embodiment the kit includes a coil pack, a modified crank pulley, and a VR sensor. The VR sensor is mounted adjacent to the modified crank pulley and is operatively connected to the coil pack. As the modified crank pulley is driven by the engine, the VR sensor is repeatedly activated and directs firing signals to the coil pack which in turn fires the engine's spark plugs. An engine computer may also be operatively connected to the coil pack and may make further adjustments to the timing or firing of the spark plugs.

The distributorless ignition kit is easily retrofitted to an engine having an existing electronic ignition system or a conventional distributor-type ignition system. In one method, the distributor, coil and original crankshaft pulley are removed from the engine. A modified crankshaft pulley is mounted to the crankshaft and a VR sensor is mounted adjacent the modified crankshaft pulley. The coil pack is mounted in or over the distributor opening and is operatively connected to the engine wiring harness, the VR sensor, the engine computer, and wires leading to the spark plugs. This automatically establishes the timing and in one preferred design the timing is now non-adjustable.

### BRIEF DESCRIPTION OF THE DRAWINGS

FIG. 1 is a schematic illustration of the distributorless ignition kit of the present invention.

FIG. 2 is a fragmentary perspective view of the coil pack of the distributorless ignition kit mounted over the distributor opening.

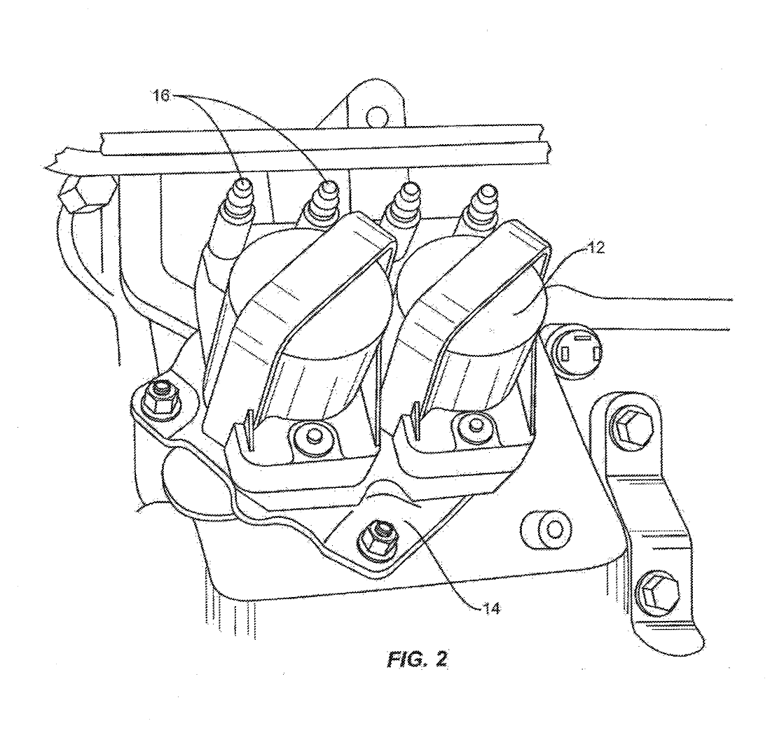

### DETAILED DESCRIPTION

With further reference to the drawings, the distributorless ignition kit is shown therein and indicated generally by the numeral 10. As will be appreciated from subsequent discussion, the distributorless ignition kit 10 is configured to be retrofitted on an internal combustion engine having, for example, a conventional coil and distributor ignition system.

First, viewing the distributorless ignition kit 10, the kit includes a coil pack 12 and a mounting plate 14 for mounting the coil pack in the opening vacated by the removal of the existing distributor. Details of the coil pack 12 are not dealt with herein because such is not per se material to the present invention and coil packs are known and appreciated by those skilled in the art. Briefly, the coil pack forms a part of an electronic ignition system and typically includes a series of coils. In some cases, there is provided one coil for firing each spark plug. In other cases, one coil may function to fire a pair of spark plugs. In any event, as will be appreciated from the subsequent discussion, the function of the coil pack 12 is to fire respective spark plugs in a particular sequence and timed fashion.

Coil pack 12 includes a number of inputs for receiving power and control or actuating signals. One input is a power input while the two other inputs are for receiving a signal from a VR sensor, to be discussed subsequent herein, and for receiving control signals from the engine computer. In addition, the coil pack includes a series of spark plug wire terminals 16. These terminals connect to electrical conductors or wires that lead to the respective spark plugs that are associated with various cylinders of the engine.

Also forming a part of kit 10 of the present invention is a modified crank pulley, indicated generally by the numeral 30. The modified crank pulley 30 includes a series of uniformly spaced notches 32 formed on the periphery thereof. These notches 32 may be referred to as timing notches and function to control the timing or actuation of the various coils in coil pack 12.

Associated with the modified crank pulley 30, is a VR sensor 18 and a mounting bracket 20 adapted to mount the VR sensor adjacent the modified crank pulley on the engine. VR sensor 18 is a variable reluctance sensor and is positioned closely adjacent the modified crank pulley 30 and senses each passing notch. In response to sensing each passing notch, the VR sensor 18 directs a firing signal to the coil pack 12, which in turn fires a spark plug.

As noted above, coil pack 12 includes a number of input terminals. To power the coil pack 12, there is provided a power cord 34 that is operatively connected between the coil pack 12 and the wiring harness of the engine. In order for the coil pack 12 to be compatible with the wiring harness, it may be necessary to provide a pin adaptor. In one embodiment, there is provided a four pin to six pin adaptor in order to make the wiring harness compatible with the coil pack 12. In addition to the power cord 34, there is provided a VR sensor cord 36. Cord 36 extends from the VR sensor 18 to the coil pack 12 and functions to direct firing signals from the VR sensor to the coil pack. Finally, there is provided an engine computer input cord 38. Cord 38 operatively interconnects the engine computer with the coil pack 12. In many applications, the engine's computer contains all necessary coding for the installation and utilization of the distributorless ignition system of the present invention. For example, the engine computer can supply control signals to the coil pack 12 that control or make timing adjustments.

Turning to the installation of the distributorless ignition kit 10, as noted above; the distributorless ignition kit is designed or adapted to be retrofitted to an engine that includes a conventional distributor type ignition system. Thus, the process or method of installation begins with removing the distributor, the distributor cap and the existing or original ignition coil. Once the distributor and distributor cap are removed, this exposes the distributor opening. Furthermore, the installation method or process entails removing the serpentine belt and the existing crankshaft pulley from the engine.

Now, the modified crankshaft pulley 30 can be installed on the crankshaft in the place formerly occupied by the existing crankshaft pulley. VR sensor 18 is mounted adjacent the modified crankshaft pulley 30. In a typical LLV postal vehicle for example, the bracket 20 and VR sensor 18 is mounted on the lower right side of the engine. This is achieved by removing one bolt from the power steering bracket and attaching the VR sensor bracket 20 on top of the power steering bracket. Other holes in the VR sensor bracket 20 align with existing holes in the engine block. Hence, the VR sensor bracket 20 can be securely anchored or stationed to the engine block such that the VR sensor 18 is properly positioned with respect to the modified crankshaft pulley 30. More particularly, VR sensor 18 is aligned with the center of the modified crankshaft pulley 30 and a gap of approximately 0.080-0.125 inches is made and maintained between the tip of the VR sensor 18 and the notched edge of the modified crankshaft pulley 30. Now, the serpentine belt is reinstalled on the engine.

Coil pack 12 is mounted in the opening formerly occupied by the distributor. In particular, the mounting bracket 14 is secured over the existing distributor opening and supports the coil pack 12. Also, the same hold down device used for the distributor is used to engage and hold down the coil pack 12. It should be appreciated that the coil pack 12 can be mounted either on the engine or at other locations in the vicinity of the engine.

Now, any adaptors required to make the coil pack 12 compatible with the wiring harness is installed. The VR sensor cord 36, in the case of one embodiment and particularly an LLV postal vehicle, is routed behind the power steering pump and up around the front of the engine and under the intake manifold to the coil pack 12. Care should be taken to make sure that the VR sensor cord 36 does not rest or lie on the exhaust manifold or interfere with any moving parts of the engine. Now, the spark plug wires are connected to the spark plug wire terminals 16 on the coil pack 12. Once it is verified that everything is installed and the wiring is properly routed, the engine may be started. The timing is set automatically and non-adjustable.

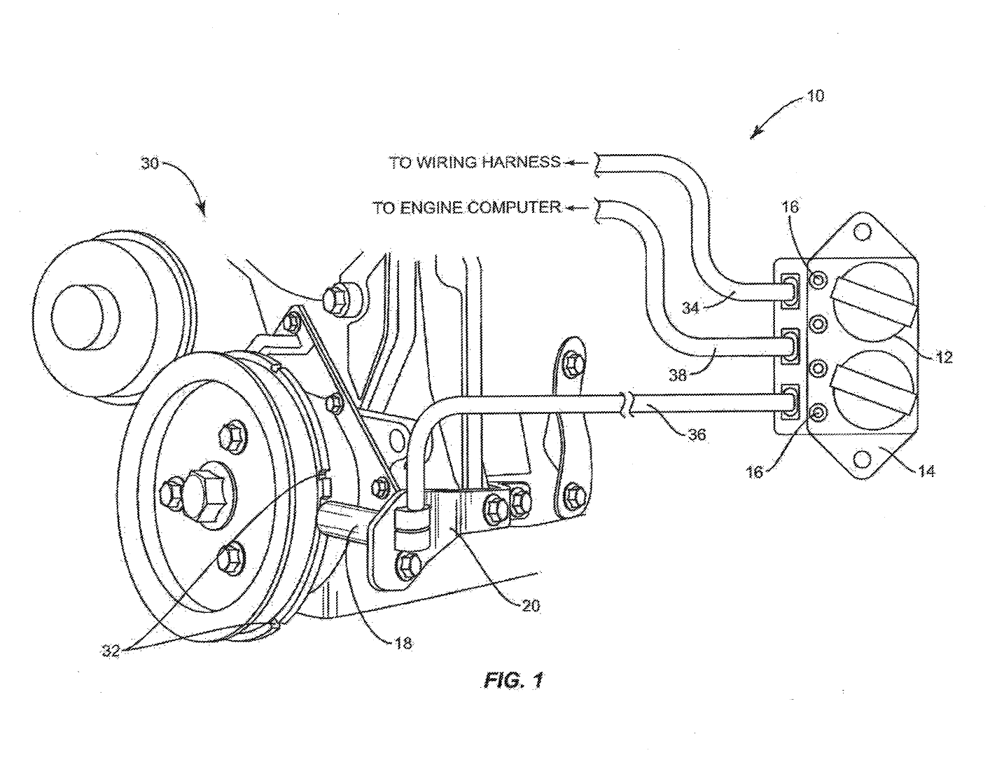

Various approaches can be utilized to set and control the timing of the distributorless ignition system 10. In one embodiment, the crank shaft pulley 30 is provided with six notches 32 that are uniformly spaced at 60 degree intervals around the crank shaft pulley. There is an additional notch, a seventh notch, that is disposed 10 degrees after one of the other notches. See FIG. 1. The seventh notch is sometimes referred to as a sync notch. The crank shaft pulley 30 and notches 32 are used for both four and six cylinder engines. The VR sensor 18 in one embodiment is positioned at approximately 92 degrees clockwise from the center line of the engine (FIG. 1) and the crank shaft pulley and the VR sensor are oriented such that the coil pack 12 will fire each cylinder at approximately 10 degrees from top dead center during grounded computer with no advancing. When the piston in cylinder number one is at top dead center the VR sensor 19 is approximately 37 degrees clockwise from the sync notch. Coil pack 12 makes the computations of when and what cylinder is fired as the timing is basically set by the locational relationship between the sensor 18 and the notches 32 of the crank shaft pulley 30. VR sensor 18 in this embodiment sends an AC voltage signal to the coil pack 12. This AC signal is utilized by the coil pack 12 to fire each of the two coils that form a part of the coil pack 12 disclosed herein. Also a signal is sent from the coil pack 12 to the vehicle computer communicating information relating to timing, engine RPM and other engine variables. With that information and information from other engine sensors, the computer adjusts timing and sends back control signals to the coil pack 12 for advancing or retarding the timing of spark plug firing. In the case of one embodiment, the engine is a 4 cylinder engine and each coil of the coil pack 12 fires two spark plugs at the same time, one coil fires cylinders 1 and 4 and the other coil fires cylinders 2 and 3. Each coil fires on both the compression and exhaust stroke. During the exhaust stroke, the mixture in the cylinder is not under pressure so the electrical resistance is low and the spark is weaker while the resistance during the compression stroke is greater and thereby requires the spark to be more intense or hotter to ignite the fuel.

The use of “including”, “comprising” or “having” and variations thereof herein is meant to encompass the items listed thereafter and equivalents thereof as well as additional items. Unless specified or limited otherwise, the terms “mounted”, “connected”, “supported” and “coupled” and variations thereof are used broadly and encompass direct and indirect mountings, connections, supports and couplings.

The present invention may, of course, be carried out in other ways than those specifically set forth herein without departing from essential characteristics of the invention. The present embodiments are to be considered in all respects as illustrative and not restrictive, and all changes coming within the meaning and equivalency range of the appended claims are intended to be embraced therein.

1. A distributorless ignition kit for retrofitting, to an existing engine having a distributor mounted in a distributor opening, the distributorless ignition kit comprising:
a. a coil pack having a power input, an engine computer signal input, and a variable reluctance (VR) sensor input;
b. the coil pack further including a series of spark plug wire terminals;
c. a mounting bracket for mounting the coil pack to the engine or adjacent the engine;
d. a modified crank shaft pulley having a series of circumferentially spaced timing notches formed thereon;
e. a VR sensor for being mounted adjacent the modified crank shaft pulley;
f. a bracket for holding the VR sensor and for mounting the VR sensor adjacent the modified crank shaft pulley; and
g. a VR sensor cord operatively interconnected between the VR sensor and the coil pack for transmitting firing signals from the VR sensor to the coil pack.

2. The distributorless ignition kit of claim 1 wherein the mounting bracket for mounting the coil pack is configured to lie over the distributor opening of the existing engine such that the coil pack is supported over the distributor opening.

3. The distributorless ignition kit of claim 1 wherein the kit further includes a power cord connected to the power input of the coil pack and extending therefrom for connecting to a wiring harness associated with the existing engine.

4. The distributorless ignition kit of claim 3 wherein the kit further includes a third cord connected to the computer signal input of the coil pack and extending therefrom, and which is operatively connected to an engine computer associated with the existing engine.

5. The distributorless ignition kit of claim 1 wherein the modified crank shaft pulley includes a series of generally uniformly spaced timing notches formed in the periphery of the modified crank shaft pulley, and further the modified crank shaft pulley includes at least one sync notch.

6. The distributorless ignition kit of claim 5 wherein the sync notch is formed in the modified crank shaft pulley closely adjacent a timing notch.

7. A method of retrofitting an existing engine with a distributorless ignition system wherein the existing engine includes a distributor extending in a distributor opening, a distributor cap and a crank shaft and a crank shaft pulley, the method comprising:
a. removing the crank shaft pulley from the crank shaft of the engine;
b. removing the distributor cap and distributor from the distributor opening in the engine;
c. installing a modified crank shaft pulley on the engine crank shaft wherein the modified crank shaft pulley includes a plurality of spaced apart timing notches formed thereon;
d. mounting a coil pack over the distributor opening;
e. mounting a VR sensor adjacent the modified crank shaft pulley such that the VR sensor may sense the plurality of timing notches on the modified crank shaft pulley as the modified crank shaft pulley rotates;
f. extending a VR sensor cord from the VR sensor to a VR sensor input on the coil pack; and
g. extending a power cord from a wiring harness associated with the engine to a power input on the coil pack.

8. The method of claim 7 wherein the modified crank shaft pulley includes a circumferential outer area and the method includes mounting the VR sensor such that the VR sensor points to the outer circumferential area of the modified crank shaft pulley.

9. The method of claim 7 including mounting the VR sensor on the lower right side of the engine.

10. The method of claim 9 including securing the VR sensor to a mounting bracket and mounting the VR sensor mounting bracket at least partially to a power steering bracket associated with the engine.

11. The method of claim 7 including securing the VR sensor to a VR sensor mounting bracket and mounting the VR sensor mounting bracket to the engine.

12. The method of claim 7 including mounting the VR sensor adjacent the modified crank shaft pulley to form a gap of approximately 0.080-0.125 inches between the VR sensor and an edge of the modified crank shaft pulley.

13. The method of claim 7 including interconnecting a computer signal cord between an engine computer associated with the engine and a computer signal input formed on the coil pack.

14. A method of retrofitting a distributorless ignition kit to an engine having a crank shaft, crank shaft pulley, and an existing ignition system, the method comprising:
a disabling the existing ignition system of the engine;
b. removing the crank shaft pulley from the crank shaft of the existing engine;
c. installing a modified crank shaft pulley on the engine crank shaft where the modified crank shaft pulley includes a series of spaced apart timing notches formed thereon;
d. installing a coil pack in the vicinity of the engine, and wherein the coil pack includes a VR sensor input;
e. mounting a VR sensor adjacent the modified crank shaft pulley such that the VR sensor is positioned where the VR sensor can, sense the timing notches formed on the modified crank shaft pulley as the crank shaft pulley is rotated; and
f. extending a VR sensor cord from the VR sensor to the VR sensor input on the coil pack such that the firing signals can be directed from the VR sensor to the coil pack.

15. The method of claim 14 wherein the engine includes a distributor opening and wherein the method includes mounting the coil pack to a mounting plate and mounting the mounting plate over the distributor opening of the engine.

16. The method of claim 14 including mounting the VR sensor adjacent the periphery of the modified crank shaft pulley and forming a gap of approximately 0.080-0.125 inches between the VR sensor and the periphery of the modified crank shaft pulley.

17. The method of claim 14 including mounting the VR sensor about a lower right-hand portion of the engine.

18. The method of claim 14 including operatively connecting the coil pack to a wiring harness associated with the engine and operatively connecting the coil pack to a computer associated with the engine.

19. The distributorless ignition kit of claim 1 wherein there is provided at least six uniformly spaced timing notches on the modified crankshaft pulley; and wherein there is provided at least one sync notch formed on the modified crankshaft pulley adjacent one of the timing notches.

20. The method of claim 14 including mounting the VR sensor in a position where the VR sensor is aimed at the center of the modified crankshaft pulley, and wherein the VR sensor is positioned such that the VR sensor can sense the timing notches of the modified crankshaft pulley as the modified crankshaft pulley rotates.
